(19) United States
(12) Patent Application Publication
(10) Pub. No.: US 2022/0121060 A1
(43) Pub. Date: Apr. 21, 2022

(54) POLARIZERS, DISPLAY MODULES AND METHODS OF PROCESSING POLARIZERS

(71) Applicant: BOE Technology Group Co., Ltd., Beijing (CN)

(72) Inventors: Xiongnan ZHANG, Beijing (CN); Paoming TSAI, Beijing (CN); Shuang DU, Beijing (CN); Xuekai YANG, Beijing (CN); Yongxiang SHI, Beijing (CN); Mengyang WEN, Beijing (CN)

(21) Appl. No.: 17/469,692

(22) Filed: Sep. 8, 2021

(30) Foreign Application Priority Data
Oct. 20, 2020 (CN) 202011126864.X

(51) Int. Cl. G02F 1/1335; G02F 1/13; G02F 1/1333

(52) U.S. Cl. CPC G02F 1/133528; G02F 1/133509; G02F 1/133305; G02F 1/1306

(57) ABSTRACT

The present application provides a polarizer, a display module and a method of processing a polarizer. The polarizer is made of stretchable materials and shaped to be a curved surface by a hat pressing process. Along a light emission direction, the polarizer includes a polarizing functional layer, configured to convert light passing through the polarizing functional layer from natural light into linearly polarized light; and a protective layer, configured to protect the polarizing functional layer. The display module includes a flexible display, the polarizer and a curved cover which are stacked sequentially along the light emission direction. The method of processing a polarizer includes: placing a polarizer to be processed on a curved surface profiling stage; and shaping the polarizer to be a curved surface corresponding to a shape of the curved surface profiling stage by a hot pressing process.

### CROSS REFERENCE TO RELATED APPLICATIONS

This application claims priority to Chinese Patent Application No. 202011126864.X entitled “POLARIZERS, DISPLAY MODULES AND METHODS OF PROCESSING POLARIZERS” filed on Oct. 20, 2020, the contents of all of which are incorporated herein by reference.

### TECHNICAL FIELD

This application relates to the field of display technologies, and in particular, to polarizers, display modules and methods for processing polarizers.

### BACKGROUND

Organic Light-Emitting Diode (OLED), as an emerging and strongly rising light-emitting device, is widely applied in the mobile display field due to its self-luminosity, high contrast, and compatibility with flexible display. Among display terminals with a smartphone as a representative, ultrahigh screen-to-body ratio and quad-curved display screen is the focus of future display competition. Quad-curved display screen, which refers to a display screen with all four edges curved to sides of the screen at a given curvature radius, is good-looking and comfortable to hold, and can have an ultrahigh screen-to-body ratio in front view.

### SUMMARY

The present application provides a polarizer, a display module and a method of processing a polarizer.

According to a first aspect of embodiments in the present application, a polarizer is provided. The polarizer is made of stretchable materials and shaped to be a curved surface by a hot pressing process. The polarizer includes: a polarizing functional layer, configured to convert light passing through the polarizing functional layer from natural light into linearly polarized light; and a protective layer, configured to protect the polarizing functional layer; where the polarizing functional layer and the protective layer are stacked sequentially along a light emission direction.

Optionally, the polarizer further includes at least one of: a first bonding layer, located between the polarizing functional layer and the protective layer; or a second bonding layer, located on a side of the polarizing functional layer away from the protective layer.

Optionally, the polarizer further includes a retardation film layer located at a side of the polarizing functional layer away from the protective layer and bonded to the polarizing functional layer by the second bonding layer.

Optionally, the polarizer further includes a third bonding layer located on a side of the retardation film layer away from the polarizing functional layer.

Optionally, a material of the protective layer is at least one of triacetyl cellulose (TAC), polymethyl methacrylate (PMMA), thermoplastic polyurethane (TPU), polyimide (PI), polyethylene terephthalate (PET), or cyclo olefin polymer (COP).

Optionally, the protective layer has a modulus of 5 MPa-7000 MPa and an elongation at break of 5% or higher.

Optionally, a material of the polarizing functional layer includes a liquid crystal material and a dichroic dye, and the polarizing functional layer is formed by a coating process.

Optionally, the polarizing functional layer is a polyvinyl alcohol (PVA) film onto which iodine or a dichroic dye is absorbed.

According to a second aspect of embodiments in the present application, a display module is provided. The display module includes a flexible display, a polarizer, and a curved cover, where the curved surface of the polarizer fits a shape of the curved cover, and the flexible display, the polarizer and the curved cover are stacked sequentially along the light emission direction. The polarizer is made of stretchable materials and shaped to be a curved surface by a hot pressing process, including: a polarizing functional layer, configured to convert light passing through the polarizing functional layer from natural light into linearly polarized and a protective layer, configured to protect the polarizing functional layer; where the polarizing functional layer and the protective layer are stacked sequentially along a light emission direction.

Optionally, the polarizer further includes at least one of: a first bonding layer, located between the polarizing functional layer and the protective layer; or a second bonding layer, located on a side of the polarizing functional layer away from the protective layer.

Optionally, the polarizer further includes a retardation film layer located at a side of the polarizing functional layer away from the protective layer, and bonded to the polarizing functional layer by the second bonding layer.

Optionally, the polarizer further includes a third bonding layer located at a side of the retardation film layer away from the polarizing functional layer.

Optionally, a material of the protective layer is at least one of triacetyl cellulose (TAC), polymethyl methacrylate (PMMA), thermoplastic polyurethane (TPU), polyimide (PI), polyethylene terephthalate (PET), or cyclo olefin polymer (COP).

Optionally, the protective layer has a modulus of 5 MPa-7000 MPa and an elongation at break of 5% or higher.

Optionally, a material of the polarizing functional layer includes a liquid crystal material and a dichroic dye; and the polarizing functional layer is formed by a coating process.

Optionally, the polarizing functional layer is a polyvinyl alcohol (PVA) film onto which iodine or a dichroic dye is absorbed.

According to a third aspect of embodiments of the present application, a method of processing a polarizer is provided. The method includes: placing a polarizer to be processed on a curved surface profiling stage; and shaping the polarizer to be a curved surface corresponding to a shape of the curved surface profiling stage by a hot pressing process. The polarizer is made of stretchable materials and includes: a polarizing functional layer, configured to convert light passing through the polarizing functional layer from natural light into linearly polarized light; and a protective layer, configured to protect the polarizing functional layer; where the polarizing functional layer and the protective layer are stacked sequentially along a light emission direction.

Optionally, the curved surface profiling stage is shaped to correspond to a curved surface of a curved cover.

Optionally, a hot pressing temperature employed in the hot pressing process is 50° C.-200° C.

Optionally, a wet steam with a humidity of 50% RH -95% RH is employed in the hot pressing process.

### BRIEF DESCRIPTION OF THE DRAWINGS

FIG. 1 is a partial cross-sectional schematic diagram of a polarizer according to some embodiments of the present application, in which end portions of the polarizer are not shown.

FIG. 2 is a cross-sectional schematic diagram of a display module according to some embodiments of the present application.

FIG. 3 is a cross-sectional schematic diagram of a stereoscopic structure obtained by laminating a polarizer and a curved cover according to some embodiments of the present application.

FIG. 4 is a flowchart of a method of processing a polarizer according to some embodiments of the present application.

FIGS. 5A-5C are schematic diagrams of processes of a method of processing a polarizer according to some embodiments of the present application.

FIG. 6 is a partial cross-sectional schematic diagram of a polarizer according to some other embodiments of the present application, in which end portions of the polarizer are not shown.

FIG. 7 is a cross-sectional schematic diagram of a display module according to some other embodiments of the present application.

### DETAILED DESCRIPTION OF THE EMBODIMENTS

Exemplary embodiments will be described in detail herein, with the illustrations thereof represented in the drawings. When the following descriptions involve the drawings, like numerals in different drawings, refer to like or similar elements unless otherwise indicated. The implementations described in the following exemplary embodiments do not represent all implementations consistent with the present application. Rather, they are merely examples of apparatuses and methods consistent with some aspects of the present application as described in detail in appended claims.

Terms in this application are used to only describe specific embodiments rather than limit the present application. Unless otherwise defined, technical terms or scientific terms used in the present application should have general meanings that can be understood by ordinary skilled in the art. In the present application, a term “one”, “a/an” or the like do not represent a quantity limitation but at least one. A term “include”, “comprise” or the like is intended to refer to that a subject of the “include” or “comprise” covers an element or object or equivalent thereof appearing as an object of the “include” or “comprise”, which does not exclude other elements or objects. A term “connect”, “connect with” or the like is not limited to a physical or mechanical connection, but includes a direct or indirect electrical connection. “A plurality of” includes two or more, which is equivalent to at least two. Singular forms such as “a/an”, ‘said”, or “the” used in the specification and the appended claims are also intended to include plurality, unless otherwise indicated in context clearly. It is also understood that the term “and/or” used herein refers to any one or all possible combinations of one or more associated listed items.

In a preparation process, a difficulty in achieving fit of functional films to quad-curved display screens hindered an advancement of mass-production of quad-curved display screens. This is because in designs with quad-curved edges, a curved surface with a certain spherical angle is formed at each of four comers. Stress and strain at these regions are not evenly distributed and are anisotropic two-dimensionally, which easily causes problems such as lamination folds in a functional film layer, such as a polarizer, attached to a quad-curved cover (e.g., a quad-curved cover glass), inadequate fit of the functional film layer, or gap between the functional film layer and the quad-curved cover.

In related art, when a polarizer and a quad-curved cover are laminated together, wrinkles appear at curved lamination regions at four corners. This is because a polarizer and a quad-curved cover to be laminated together are different in size. A polarizer is provided with a support substrate such as cyclo olefin polymer (COP), triacetyl cellulose (TAC), or polymethyl methacrylate (PMMA) for protection. These protective materials usually have a high modulus, and are not easily stretched and shrunk, which results in an uneven stress distribution of lamination interfaces at the curved lamination regions and further causes wrinkling of the polarizer. In addition, inadequate lamination usually results in air bubbles, which tends to cause cracks at a film interface.

As shown in FIG. 1, according to some embodiments of the present application, a polarizer 10 is provided. The polarizer 10 is made of stretchable materials and shaped to be a curved surface by a hot pressing process. The curved surface includes a dual-curved surface, a quad-curved surface, a spherical surface and any other three-dimensional curved surface. The polarizer 10 is made of stretchable materials, that is, the polarizer 10 has stretchability and shrinkability.

The polarizer 10 includes a retardation film layer 11, a polarizing functional layer 12 and a protective layer 13 stacked sequentially along a light emission direction L.

The protective layer 13 is configured to protect the polarizing functional layer 12. The protective layer 13 is made of a stretchable material, that is, the protective layer 13 has stretchability and shrinkability. In some embodiments, the protective layer 13 has a modulus of 5 MPa-7000 MPa and an elongation at break of 5% or higher.

A material of the protective layer 13 may be at least one of TAC, PMMA, thermoplastic polyurethane (TPU), polyimide (PI), polyethylene terephthalate (PET), or COP.

The polarizing functional layer 12 is located at a side of the protective layer 13 and configured to convert light passing through the polarizing functional layer 12 from natural light into linearly polarized light. The polarizing functional layer 12 is made of a stretchable material. In this embodiment, the polarizing functional layer 12 is a polyvinyl alcohol (PVA) film onto which iodine or a dichroic dye is adsorbed. A content of the iodine or dichroic dye in the polarizing functional layer 12 may be such that polarization function can be achieved and no further limitations are made herein. It is noted that the PVA film has a strong recovery stress, i.e., stretchability and shrinkability, due to its process of stretching.

The retardation film layer 11 is located at a side of the polarizing functional layer 12 away from the protective layer 13. The retardation film layer 11 can convert linearly polarized light into circularly polarized light or elliptically polarized light, and thus can improve, when used in combination with the polarizing functional layer 12, a contrast of a display in ambient light. The retardation film layer 11 may also be made of a stretchable material. That is, each layer of the polarizer 10 is made of a stretchable material, so that an overall stretchability of the polarizer 10 can be achieved.

Optionally, the polarizer 10 may further include a first bonding layer 14, a second bonding layer 15 and a third bonding layer 16. The first bonding layer 14 is located between the polarizing functional layer 12 and the protective layer 13 to bond the polarizing functional layer 12 and the protective layer 13 together. The second bonding layer 15 is located on a side of the polarizing functional layer 12 away from the protective layer 13 to bond the polarizing functional layer 12 and the retardation film layer 11 together. The third bonding layer 16 is located on a side of the retardation film layer 11 away from the polarizing functional layer 12 to bond the polarizer 10 to another film layer or a flexible display.

It is noted that in an embodiment of a polarizer without the retardation film layer 11, the polarizer 10 can be directly bonded to another film layer or a flexible display by the second bonding layer 15.

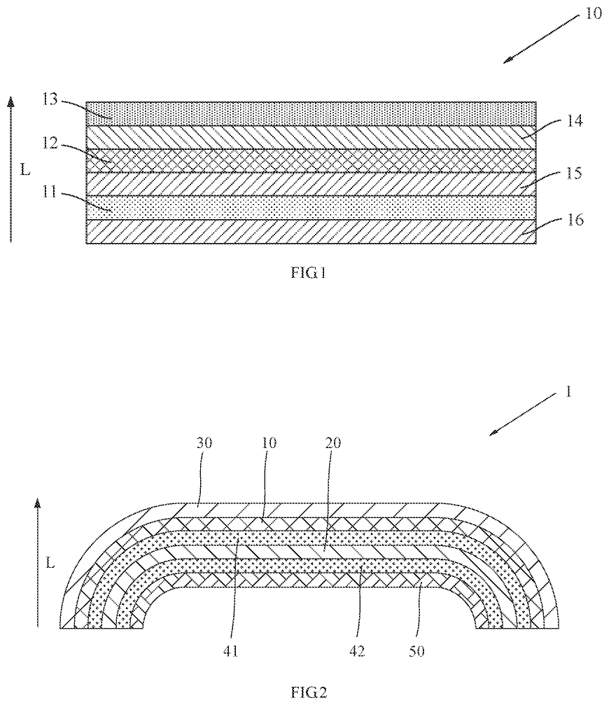

As shown in FIG. 2, according to some embodiments of the present application, a display module 1 is provided. The display module 1 includes a flexible display 20, the polarizer 10 described above and a curved cover 30 stacked sequentially along a light emission direction L, where a curved shape of the polarizer 10 fits with a curved shape of the curved cover 30. The curved surface of the curved cover 30 may be a dual-curved surface, a quad-curved surface, a spherical surface or any other three-dimensional curved surface.

The flexible display 20 is adhered to a side of the polarizer 10 away from the curved cover 30 by a first adhesive layer 41.

The display module I may further include a support layer 50 which is adhered to a side of the flexible display 20 away from the polarizer 10 by a second adhesive layer 42.

In the polarizer 10 and the display module 1 according to this embodiment, the polarizer 10 is made of stretchable materials and shaped to be a curved surface by a hot pressing process, such that the polarizer 10 and the curved cover 30 can fully fit each other to achieve a technical effect of a flat appearance without wrinkles, and a curved lamination region is optically stable and has no light leakage.

It is noted that in this embodiment, the curved cover is a quad-curved cover. The polarizer in the present application can also be fully and completely bonded to the curved cover at curved surfaces with a certain spherical angle (i.e., curved lamination regions) formed at four corners. Thus, a beneficial technical effect of a flat appearance without wrinkles can also be achieved.

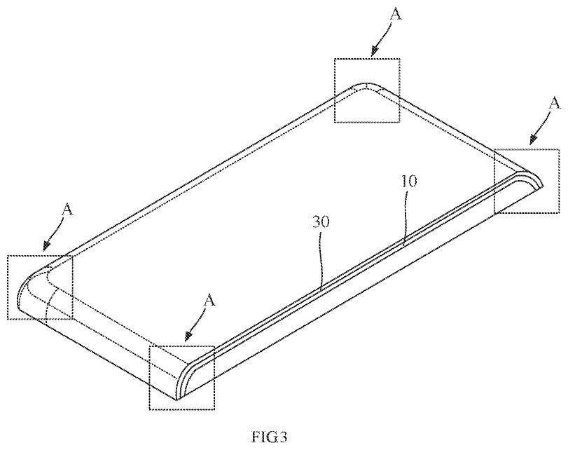

As shown in FIG. 3, when the polarizer 10 and the curved cover 30 are laminated together, the polarizer 10 is fully attached to the curved cover 30 in the curved lamination regions A without wrinkles generated, thus achieving a beneficial technical effect of a desirable flat appearance.

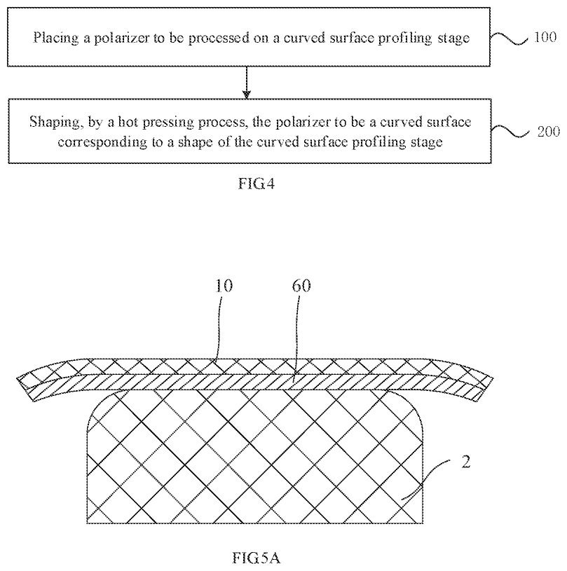

Some embodiments of the present application further provide a method of processing a polarizer. FIG. 4 is a flowchart of a method of processing a polarizer according to some embodiments of the present application. As shown in FIG. 4, the method of processing a polarizer includes the following steps 100 and 200.

At step 100, a polarizer to be processed is placed on a curved surface profiling stage.

At step 200, the polarizer is shaped to be a curved surface corresponding to a shape of the curved surface profiling stage by a hot pressing process.

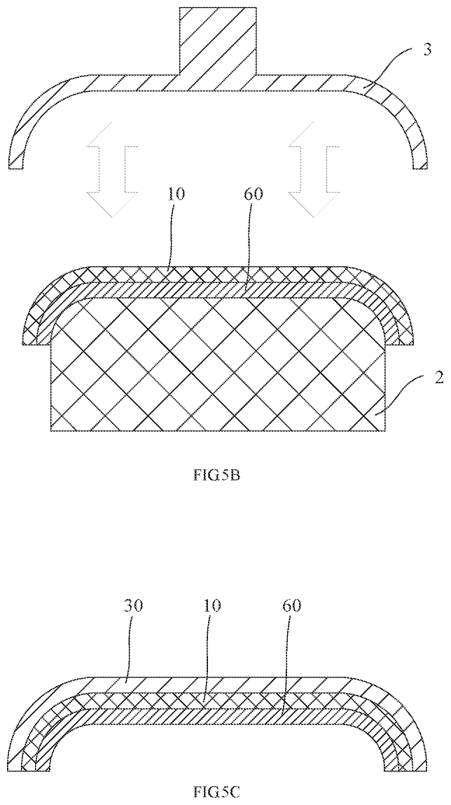

In step 100, as shown in FIG. 5A, the polarizer 10 to be processed is placed on the curved surface profiling stage 2. A carrier film 60 can be placed between the polarizer 10 to be processed and the curved surface profiling stage 2, that is, the carder film 60 is placed under the polarizer 10. In step 200, as shown in FIG. 5B, by hot-pressing toward the curved surface profiling stage 2 with a hot pressing plate 3, the polarizer 10 is shaped to be a curved surface corresponding to the shape of the curved surface profiling stage 2. That is, by hot-pressing toward the curved surface profiling stage 2 with the hot pressing plate 3, the polarizer 10 and the carrier film 60 can be laminated together, and thus the polarizer 10 and the carrier film 60 both have the curved surface corresponding to the shape of the curved surface profiling stage 2.

After step 200 is completed, the polarizer 10 and the carrier film 60 are removed from the curved surface profiling stage 2. Then, as shown in FIG. 5C, the polarizer 10 is attached to an underside of the curved cover 30 with the carrier film 60 as a carrier of the polarizer 10. Thus, by attaching the polarizer 10 to the carrier film 60 so as to make the carrier film 60 serve as a carrier of the polarizer 10, pickup and handling of the polarizer 10 and attaching the polarizer 10 to the curved cover 30 are facilitated. After the polarizer 10 is attached to the curved cover 30, the carrier film 60 may be peeled off or retained. A material of the carrier film 60 may be ultra-thin glass, TPU, PI, COP, PET or the like.

In some embodiments, the curved surface profiling stage 2 is shaped to correspond to a curved shape of the curved cover 30. In this way, the polarizer 10 can be formed into a curved surface matched with a shape of the curved cover 30 by means of the curved surface profiling stage 2, so that a close fit without gaps between the polarizer 10 and the curved cover 30 can be achieved.

In some embodiments, a hot pressing temperature employed in the hot pressing process is 50° C. -200° C. The higher the temperature is, the faster the polarizer 10 shrinks.

In some embodiments, wet stream with a humidity of 50% RH-95% RH is employed in the hot pressing process. Supplemented with a warm wet steam of a certain condition, the polarizer 10 can shrink faster. The higher the humidity is, the faster the polarizer 10 shrinks.

A duration of the hot pressing process is 3 s-120 s.

In the method of processing a polarizer in the embodiment, with the polarizer made of a stretchable material and shaped to be a curved surface matched with the curved cover by the hot pressing process, fully fit between the polarizer and the curved cover is facilitated, thus achieving a beneficial technical effect of a flat appearance without wrinkles. Further, curved lamination regions are stable in optical characteristics and have no light leakage.

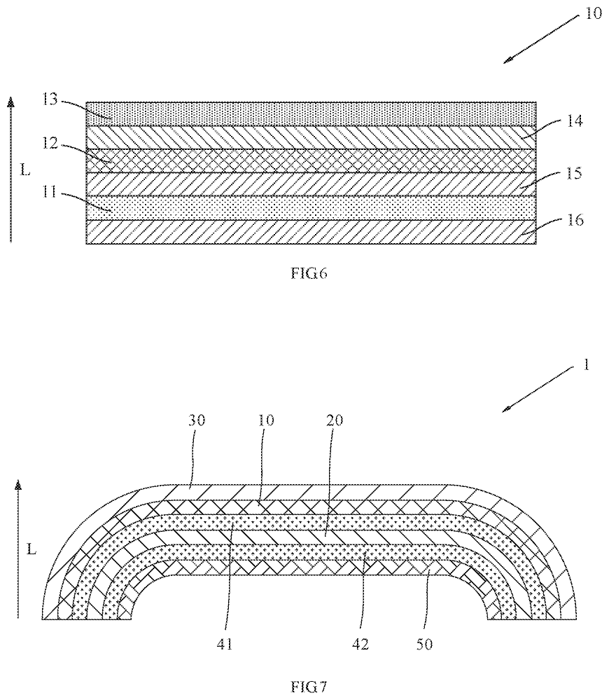

As shown in FIG. 6, the entire structure of a polarizer in some other embodiments of the present application is substantially identical to that of the polarizer in the above embodiments, except that a polarizing functional layer 12 thereof is different from the above embodiments in materials. A material of the polarizing functional layer 12 includes a liquid crystal material and a dichroic dye. The dichroic dye includes Azo dye, anthraquinone dye, polycyclic dye and the like, and may also be a mixture of the above dyes in order to ensure a polarization effect in a wide wavelength range. A content of the dichroic dye in the polarizing functional layer 12 is such that polarization function can be achieved and no further limitations are made herein. The working principle of this polarizing functional layer is that by means of light-driven alignment, the liquid crystal material has a fixed orientation, while the dichroic dye in the liquid crystal material has a same orientation arrangement, and thus a function of linear polarization is achieved.

The polarizing functional layer 12 is formed by a coating process. By the coating process, the polarizing functional layer 12 can be lighter and thinner, more resistant to temperature and humidity and can withstand larger deformation.

As shown in FIG. 7, an embodiment of the present application further provides a display module. The entire structure of the display module 1 according to this embodiment is substantially identical to that of the display module according to the above embodiments, except that the polarizer 10 in the display module 1 is the polarizer 10 in this embodiment, that is, a material of the polarizing functional layer 12 includes a liquid crystal material and a dichroic dye. The polarizing functional layer 12 may be formed by a coating process.

In the polarizer 10 and the display module 1 according to this embodiment, with the polarizer 10 made of a stretchable material and shaped to be a curved surface corresponding to the curved cover 30 by a hot pressing process, a fully fit between the polarizer 10 and the curved cover 30 can be achieved, thus achieving a beneficial technical effect of a flat appearance without wrinkles. Further, curved lamination regions are stable in optical characteristics and have no light leakage.

The method of processing a polarizer in this embodiment is identical to the above embodiment and thus not repeated herein.

The above are only some preferred embodiments of this application, not intended to limit this application. Any modification, equivalent, improvement, etc., within the spirit and principles of this application, shall be involved in the scope of protection of this application.

1. A polarizer, wherein the polarizer is made of stretchable materials and shaped to be a curved surface by a hot pressing process, and the polarizer comprises:
a polarizing functional layer, configured to convert light passing through the polarizing functional layer from natural light into linearly polarized light; and
a protective layer, configured to protect the polarizing functional layer;
wherein the polarizing functional layer and the protective layer are stacked sequentially along a light emission direction.

2. The polarizer according to claim 1, further comprising at least one of:
a first bonding layer, located between the polarizing functional layer and the protective layer; or
a second bonding layer, located on a side of the polarizing functional layer away from the protective layer.

3. The polarizer according to claim 2, further comprising:
a retardation film layer, located at a side of the polarizing functional layer away from the protective layer, and bonded to the polarizing functional layer by the second bonding layer.

4. The polarizer according to claim 3, further comprising:
a third bonding layer, located on a side of the retardation film layer away from the polarizing functional layer

5. The polarizer according to claim 1, wherein a material of the protective layer is at least one of triacetyl cellulose (TAC), polymethyl methacrylate (PMMA), thermoplastic polyurethane (TPU), polyimide (PI), polyethylene terephthalate (PET), or cyclo olefin polymer (COP).

6. The polarizer according to claim 1, wherein the protective layer has a modulus 5 MPa-7000 MPa and an elongation at break of 5% or higher.

7. The polarizer according to claim 1, wherein a material of the polarizing functional layer comprises a liquid crystal material and a dichroic dye, and the polarizing functional layer is formed by a coating process.

8. The polarizer according to claim 1, wherein the polarizing functional layer is a polyvinyl alcohol (PVA) film onto which iodine or a dichroic dye is absorbed.

9. A display module, comprising:
a flexible display; and
a polarizer, made of stretchable materials and shaped to be a curved surface by a hot pressing process, comprising:
a polarizing functional layer, configured to convert light passing through the polarizing functional layer from natural light into linearly polarized light; and
a protective layer, configured to protect the polarizing functional layer;
wherein the polarizing functional layer and the protective layer are stacked sequentially along a light emission direction; and
a curved cover;
wherein the curved surface of the polarizer fits a shape of the curved cover, and the flexible display, the polarizer and the curved cover are stacked sequentially along the light emission direction.

10. The display module according to claim 9, wherein the polarizer further comprises at least one of:
a first bonding layer, located between the polarizing functional layer and the protective layer; or
a second bonding layer, located at a side of the polarizing functional layer away from the protective layer.

11. The display module according to claim 10, wherein the polarizer further comprises:
a retardation film layer, located at a side of the polarizing functional layer away from the protective layer, and bonded to the polarizing functional layer by the second bonding layer.

12. The display module according to claim 11, wherein the polarizer further comprises:
a third bonding layer, located on a side of the retardation film layer away from the polarizing functional layer.

13. The display module according to claim 9, wherein a material of the protective layer is at least one of triacetyl cellulose (TAC), polymethyl methacrylate (PMMA), thermoplastic polyurethane (TPU), polyimide (PI), polyethylene terephthalate (PET), or cyclo olefin polymer (COP).

14. The display module according to claim 9, wherein the protective layer has a modulus of 5 MPa-7000 MPa and an elongation at break of 5% or higher.

15. The display module according to claim 9, wherein a material of the polarizing functional layer comprises a liquid crystal material and a dichroic dye, and the polarizing functional layer is formed by a coating process.

16. The display module according to claim 9, wherein the polarizing functional layer is a polyvinyl alcohol (PVA) film onto which iodine or a dichroic dye is absorbed.

17. A method of processing a polarizer, comprising:
placing a polarizer to be processed on a curved surface profiling stage; and
shaping the polarizer to be a curved surface corresponding to a shape of the curved surface profiling stage by a hot pressing process;
wherein the polarizer is made of stretchable materials and comprises:
a polarizing functional layer, configured to convert light passing through the polarizing functional layer from natural light into linearly polarized light; and
protective layer, configured to protect the polarizing functional layer,
wherein the polarizing functional layer and the protective layer are stacked sequentially along a light emission direction.

18. The method according to claim 17, wherein the curved surface profiling stage is shaped to correspond to a curved surface of a curved cover.

19. The method according to claim 17, wherein a hot pressing temperature employed in the hot pressing process is 50° C.-200° C.

20. The method according to claim 7, wherein a wet steam with a humidity of 50% RH-95% RH is employed in the hot pressing process.
